(19) United States
(12) Patent Application Publication
(10) Pub. No.: US 2003/0182605 A1
(43) Pub. Date: Sep. 25, 2003

(54) Process and device for identifying and designating radially-oriented patterns of defects on a data-storage medium

(76) Inventors: Robert L. Short, Washington, UT (US); Eric R. Peters, Roy, UT (US); Daniel D. Rochat, Ogden, UT (US); Kenneth D. Austin, Perry, UT (US)

Correspondence Address: Frank T. Carroll, WOODCOCK WASHBURN KURTZ, MACKIEWICZ & NORRIS LLP, One Liberty Place - 46th Floor, Philadelphia, PA, 19103, US

(21) Appl. No.: 09/957,349

(22) Filed: Sep. 20, 2001

Related U.S. Application Data
(63) Continuation-in-part of application No. 09/458,649, filed on Dec. 10, 1999.
(60) Provisional application No. 60/111,824, filed on Dec. 11, 1998.

(51) Int. Cl. G11C 29/00; H04L 1/22; H04B 1/74; H02H 3/05; H05K 10/00; H03K 19/003

(52) U.S. Cl. 714/718; 714/42

(57) ABSTRACT

A process for identifying and designating a radially-oriented defect pattern on a data-storage medium comprises determining an angular position of one or more pre-identified defective data sectors on the data-storage medium by counting a number of servo sectors on the data-storage medium that pass a predetermined reference point. The process also comprises defining a radially-oriented pattern of the pre-identified defective data sectors based on a predetermined relationship between: a number of the pre-identified defective data sectors having substantially identical angular positions; and radial spacing between the pre-identified defective data sectors having substantially identical angular positions. The process further comprises writing defect-identification information to data sectors having locations that substantially coincide with the radially-oriented pattern of the pre-identified defective data sectors.

This application is a continuation-in-part of prior application Ser. No. 09/458,649, filed on Dec. 10, 1999 and claiming priority to U.S. provisional patent application serial No. 60/111,824, filed on Dec. 11, 1998.

### FIELD OF THE INVENTION

The present invention relates to data-storage media. More particularly, the present invention provides a process and a device for identifying and designating radially-oriented patterns of defects on a data-storage medium.

### BACKGROUND OF THE INVENTION

Data-storage media typically store digital information in discrete locations known as data sectors. The ability of the data sectors of a particular data-storage medium to properly store information is usually checked at some point before the medium reaches the end user. This check is commonly known as a verification. An excessive amount of defective sectors on a data-storage medium may necessitate scrapping the medium. Alternatively, the medium may be utilized after steps have been taken to avoid any future use of the defective sectors.

The verification process is performed by a device commonly referred to as a verifier. The verifier writes a predetermined data set to individual data sectors on the medium, reads the data back, and compares the as-written and the as-read data. Discrepancies between the as-written and the as-read data from a particular data sector are interpreted as an indication that the particular data sector is defective. A defect-identification code is written to each defective data sector so identified. The defect-identification code is recognized by data-storage devices in which the medium is subsequently used, and indicates that data should not be written to or read from a particular data sector.

The head-disk interface of the verifier is typically able to write and read data to and from data sectors having some type of imperfections thereon. The ability of the verifier's head-disk interface to tolerate such imperfections is often greater than that of the data-storage devices in which the data-storage medium is subsequently used. Hard, non-recoverable read-write errors (and an accompanying data loss) occur when a data-storage device unsuccessfully attempts to write or read data to or from a data-storage medium. Hence, it is highly desirable to identify data sectors on a particular data-storage medium that will be unusable by an end-user's device, and to designate those data sectors as defective.

Coating blisters are a type of imperfection that is often present on data-storage media. FIG. 1 depicts a data-storage medium 4 comprising a data-storage surface 4a having a coating blister 5 thereon. FIG. 1 also depicts an actuator assembly 2 of a disk drive in which the data-storage medium 4 may be used. A read-write head 3 is positioned at an end of the actuator assembly 2 for writing and reading data to and from the data-storage surface 4a. The disk drive rotates the data-storage medium 4 in the direction denoted by the arrow 1. The actuator assembly 2 moves read-write head 3 linearly, in the direction denoted by the arrow 8, to permit the read-write head 3 to access a substantial entirety of the data-storage surface 4a.

Blisters such as the blister 5 usually interfere with the proper spacing between the read-write head 3 and the data-storage surface 4a. This interference manifests itself as a radially-oriented pattern 7 of defective data sectors when the actuator assembly 2 moves the read-write head 3 linearly across the data-storage surface 4. In other words, contact between the read-write head 3 and the blister 5 as the read-write head is translating linearly (or radially in relation to the data-storage surface 4a) prevents the read-write head from writing and reading data to and from data sectors that are radially aligned with, and located proximate the blister 5. This problem is exacerbated by ongoing consumer demand for data-storage media having increased aerial densities (and smaller spacing between data sectors).

The specific data sectors that are rendered unusable by the effects of the blister 5 depend on the head-disk interface between data-storage medium 10 and the particular data-storage device in which the data-storage medium 10 is used. For example, the verifier used during the verification process for the data-storage medium 4, as noted above, is usually less sensitive to defects in the data-storage surface 4a than a typical end-user device. Thus, an end user may encounter hard, non-recoverable read-write errors when using the data-storage medium 4 due to the presence of data sectors that are unusable the end-user's device, but were not identified and designated so during the verification process. A need therefore exists for a process and a device for identifying and designating radially-oriented patterns of data sectors that may be usable by one type of data-storage device, but unusable by another.

### SUMMARY OF THE INVENTION

A presently-preferred process for identifying and designating a radially-oriented defect pattern on a data-storage medium comprises determining an angular position of one or more pre-identified defective data sectors on the data-storage medium by counting a number of servo sectors on the data-storage medium that pass a predetermined reference point. The presently-preferred process also comprises defining a radially-oriented pattern of the pre-identified defective data sectors based on a predetermined relationship between: a number of the pre-identified defective data sectors having substantially identical angular positions; and radial spacing between the pre-identified defective data sectors having substantially identical angular positions. The presently-preferred process further comprises writing defect-identification information to data sectors having locations that substantially coincide with the radially-oriented pattern of the pre-identified defective data sectors.

A presently-preferred process for identifying and designating a radially-oriented pattern of potentially unusable data sectors on a data-storage medium having servo sectors and data tracks defined thereon comprises reading a defect-identification code from pre-identified defective data sectors on the data-storage medium. The presently-preferred process also comprises calculating angular positions of the pre-identified defective data sectors by counting a number of the servo sectors that pass a predetermined reference point and correlating the number with an angular displacement of the data-storage medium. The presently-preferred process further comprises determining radial positions of the pre-identified defective data sectors based on positions of the data tracks on which the pre-identified defective data sectors are located.

The presently-preferred process for identifying and designating a radially-oriented pattern of potentially unusable data sectors on a data-storage medium having servo sectors and data tracks defined thereon further comprises defining a radially-oriented defect pattern by identifying a predetermined number of the pre-identified defective data sectors that have substantially identical angular positions, and are located within a predetermined radial distance of each other. The presently-preferred process also comprises writing the defect-identification code to one or more data sectors, other than the pre-identified defective data sectors, that have an angular position that is substantially identical to an angular position of the radially-oriented defect pattern, and a radial position between a radially outermost and a radially innermost of the pre-identified defective data sectors in the radially-oriented defect pattern.

A presently-preferred process for marking a pattern of potentially unusable data sectors on a data-storage medium comprises checking data sectors on the data-storage medium for the presence of a pre-written defect-identification code, and determining angular and radial positions of the data sectors having the defect-identification code pre-written thereto. The presently-preferred process further comprises identifying the pattern of potentially unusable data sectors by checking for a predetermined number of the data sectors having the defect-identification code written thereto that have substantially identical angular positions, and are radially spaced within a predetermined distance. The presently-preferred process also comprises filling in and extending the pattern of potentially unusable data sectors.

Another presently-preferred process for identifying and designating a radially-oriented defect pattern on a substantially circular data-storage medium comprises determining an angular position of one or more pre-identified defective data sectors on the data-storage medium. The presently-preferred process also comprises defining a radially-oriented pattern of the pre-identified defective data sectors based on a predetermined relationship between a number of the pre-identified defective data sectors having substantially identical angular positions, and radial spacing between the pre-identified defective data sectors having substantially identical angular positions. The presently-preferred process further comprises writing predetermined identification information to data sectors having locations that substantially coincide with the radially-oriented pattern of the pre-identified defective data sectors.

Another presently-preferred process for identifying and designating a radially-oriented defect pattern on a substantially circular data-storage medium comprises determining an angular position of a defective data sector on the data-storage medium by counting a number of servo sectors on the data-storage medium that pass a predetermined reference point, and determining a radial position of the defective data sector based on a location of a data-track on which the defective data sector is positioned.

A presently-preferred device for identifying and designating a radially-oriented defect pattern on a data-storage medium comprises a microprocessor, a memory-storage device electrically coupled to the microprocessor, and a read-write head electrically coupled to the microprocessor for writing and reading information to and from the data-storage medium. The presently-preferred device further comprises a set of computer-executable instructions stored on the memory-storage device.

The computer-executable instructions of the presently-preferred device determine an angular position of one or more pre-identified defective data sectors on the data-storage medium by counting a number of servo sectors on the data-storage medium that pass a predetermined reference point. The computer-executable instructions also define a radially-oriented pattern of the pre-identified defective data sectors based on a predetermined relationship between a number of the pre-identified defective data sectors having substantially identical angular positions, and radial spacing between the pre-identified defective data sectors having substantially identical angular positions. The computer-executable instructions also cause the read-write head to write defect-identification information to data sectors having locations that substantially coincide with the radially-oriented pattern of the pre-identified defective data sectors.

### BRIEF DESCRIPTION OF THE DRAWINGS

The foregoing summary, as well as the following detailed description of a presently-preferred embodiment, is better understood when read in conjunction with the appended drawings. For the purposes of illustrating the invention, there is shown in the drawings an embodiment that is presently preferred, it being understood, however, that the invention is not limited to the specific methods and instrumentalities disclosed. In the drawings:

FIG. 1 is a diagrammatic illustration of a data-storage medium having a coating blister on a data-storage surface thereof, and a portion of a disk drive capable of writing and reading data to and from the data-storage medium;

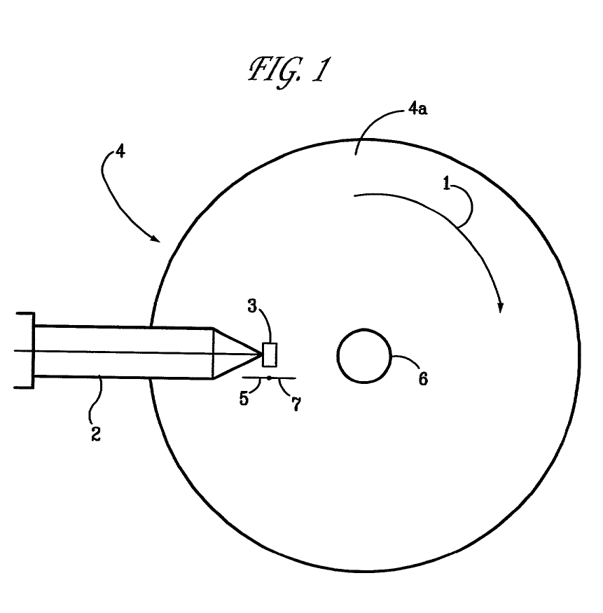

FIG. 2 is a diagrammatic illustration of a data-storage medium that can be used in conjunction with the present invention;

FIG. 3 is a diagrammatic illustration showing a verifier and a servo-writer capable of formatting and verifying the data-storage medium shown in FIG. 2;

FIG. 4 is a block diagram depicting the verifier shown in FIG. 3;

FIG. 5 is a flow diagram showing an exemplary verification process that can be performed on the data-storage medium shown in FIG. 2; and

FIG. 6 is a flow diagram depicting a process for identifying and designating radially-oriented patterns of defects on a data-storage medium, such as the data-storage medium shown in FIG. 2, in accordance with the present invention.

### DESCRIPTION OF PREFERRED EMBODIMENTS

The present invention provides a process for identifying and designating radially-oriented patterns of defects on a data-storage medium. The invention also provides a device for performing such a process.

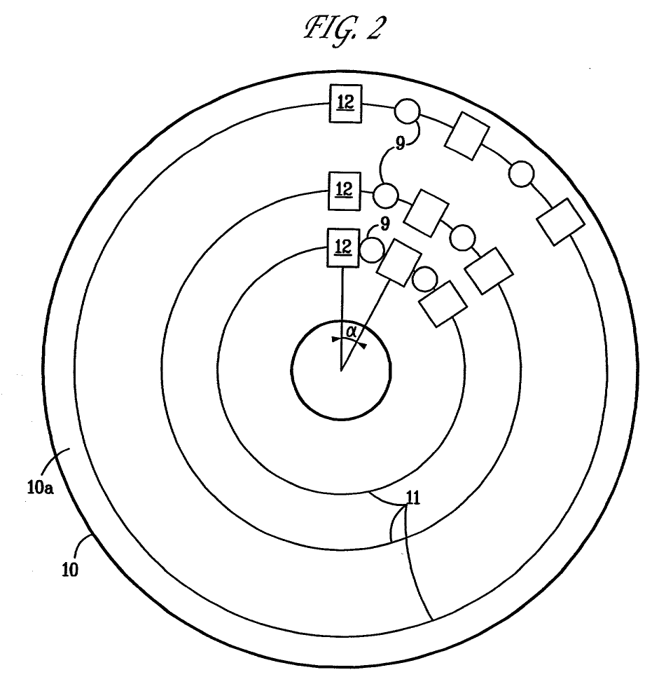

FIG. 2 is a diagrammatic illustration showing an exemplary data-storage medium 10 that can be used in conjunction with the present invention. The medium 10 may be housed within a data-storage cartridge (not shown) during use with a removable-media disk drive. The medium 10 may also be used without a housing when embodied as a CD-ROM, or when installed in a fixed-media drive. The medium 10 is used in conjunction with a disk-drive system (also not shown) to store and retrieve digital information. The medium 10 may be one of several different types, e.g., magnetic or optical floppy media, magnetic or optical hard media.

The data-storage medium 10 must be formatted in order to properly interface with a disk drive. Details concerning the formatting process are presented herein to assist in an understanding of the invention. A number of concentric data tracks 11 are defined over a data-storage surface 10a of the data-storage medium 10 during the formatting process. The data tracks 11 are defined by servo sectors 12. Data sectors 9 are disposed between adjacent servo sectors 12. The data sectors 9 are utilized for the storage of user data. (For clarity, the data tracks 11, servo sectors 12, and data-sectors 9 are not drawn to scale in FIG. 2. Also, two or more servo sectors 12 may be disposed between adjacent data sectors 9, unlike the arrangement shown in FIG. 2.)

A fixed number of servo sectors 12 are disposed in equal angular increments along each data track 11 (this angular increment is denoted in FIG. 2 by the symbol “α”). A total of 120 servo sectors 12 are placed along each data track 11 on the exemplary data-storage medium 10. Thus, the angle α has a value of three degrees on the medium 10.

The servo sectors 12 are utilized by the electronics of a disk drive to provide positional guidance to the read-write head of the drive. More specifically, the disk-drive electronics read positional data from the servo sectors 12 as the servo sectors 12 pass the read-write head during data storage and retrieval operations. The electronics utilize this data for positional guidance and, in conjunction with a servo loop controller, maintain the read-write head over (or under) a particular data track 11 on the data-storage medium 10.

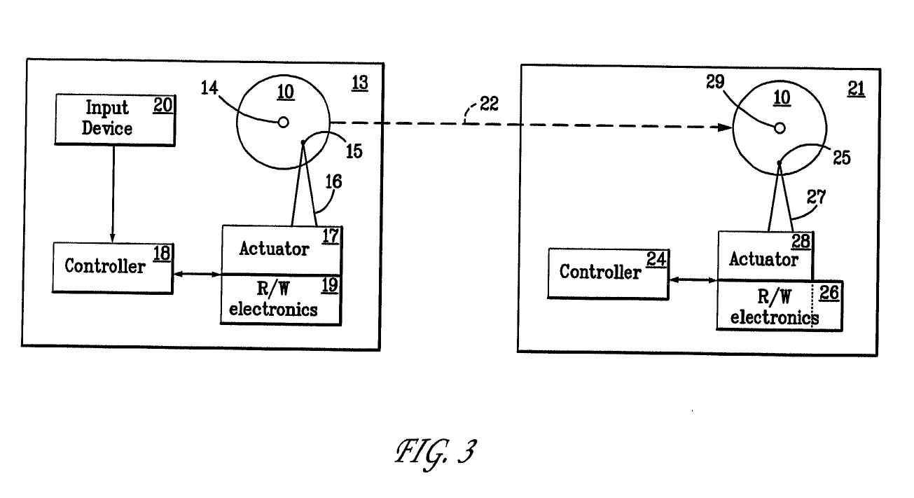

Some types of removable data-storage media, e.g., the cartridge used in the well-known ZIP drive, are formatted in a two-step process. These steps comprise a servo-writing process followed by a check, or verification, of the servo-writing process. The formatting operation can be conducted using the hardware shown in diagrammatical form in FIG. 3.

The servo-writing process is performed by a servo-writer 13. The servo-writer 13 is a finely-calibrated device that writes servo sectors 12 onto a data-storage surface 10a of the medium 10 at precise intervals. The servo-writer 13 comprises a spindle 14 for suspending and rotating the medium 10; a read-write head 15 for writing and reading servo information to and from the medium 10; an arm 16 for moving the read-write head 15 across the surface 10a of the medium 10; an actuator 17 for controlling the movement of the arm 16; a controller 18 for executing and controlling the servo-writing process; and read-write electronics 19 that transform the electromagnetic signals used by the read-write head 15 to and from the digital format utilized by the controller 18 (see FIG. 3). Additionally, the servo-writer 13 comprises an input device 20, e.g., a keyboard, that serves as an operator interface. Skilled artisans will appreciate that the servo-writer 13 can be one of many commercially-available units, e.g., the Phase Metric/Helios MS 5000, appropriately modified to accept a particular type of data-storage medium 10.

The data-storage medium 10 is transported to a verifier 21 after completion of the servo-writing process (this step is illustrated by a dashed line 22 in FIG. 3). The verifier 21 performs a check of the medium 10 to ensure that the medium 10 is able to store data in a proper manner. This check is performed by writing test data to the medium 10, reading back the test data, and comparing the as-written data and the as-read data.

The verifier 21 is a data-storage system that is programmed with a set of computer-executable instructions 23 that identify defective data sectors 9. The instructions 23 identify defective data sectors 9 by writing and reading test data to and from the medium 10, and comparing the as-written and the as-read data in the above-described manner. The verifier 21 can be a common removable-media disk drive that has been reprogrammed with the computer-executable instructions 23. In the exemplary embodiment, the verifier 21 is a standard ZIP disk drive.

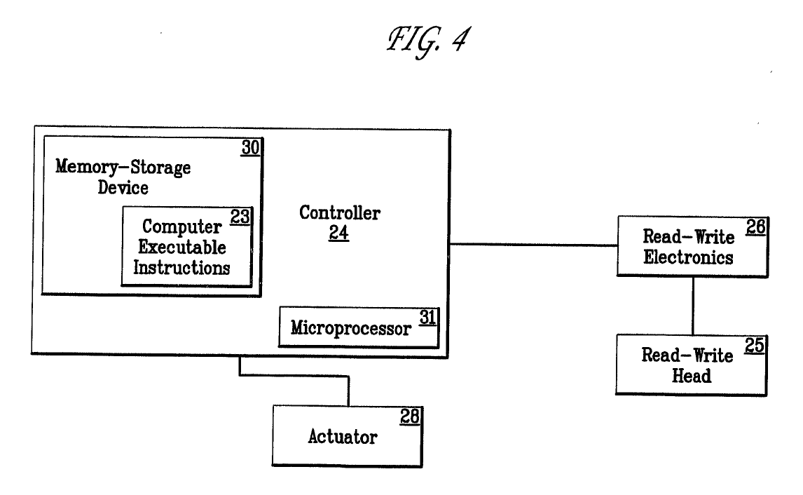

The major components of the verifier 21 are illustrated diagrammatically in FIG. 3 and in block-diagram form in FIG. 4. The verifier 21 comprises a controller 24 that controls the verification process; a read-write head 25 for writing and reading data to and from the medium 10; read/write electronics 26 that transform the electromagnetic signals used by the head 25 to and from the digital format utilized by the controller 24; an arm 27 for suspending and moving the read-write head 25 over the surface of the medium 10; an actuator 28 for moving the arm 27 in response to commands from the controller 24; and a spindle 29 for supporting and rotating the medium 10. The controller 24 comprises a memory-storage device 30 upon which the computer-executable instructions 23 are stored (see FIG. 4). The controller 24 also comprises a microprocessor 31 that executes the computer-executable instructions 23.

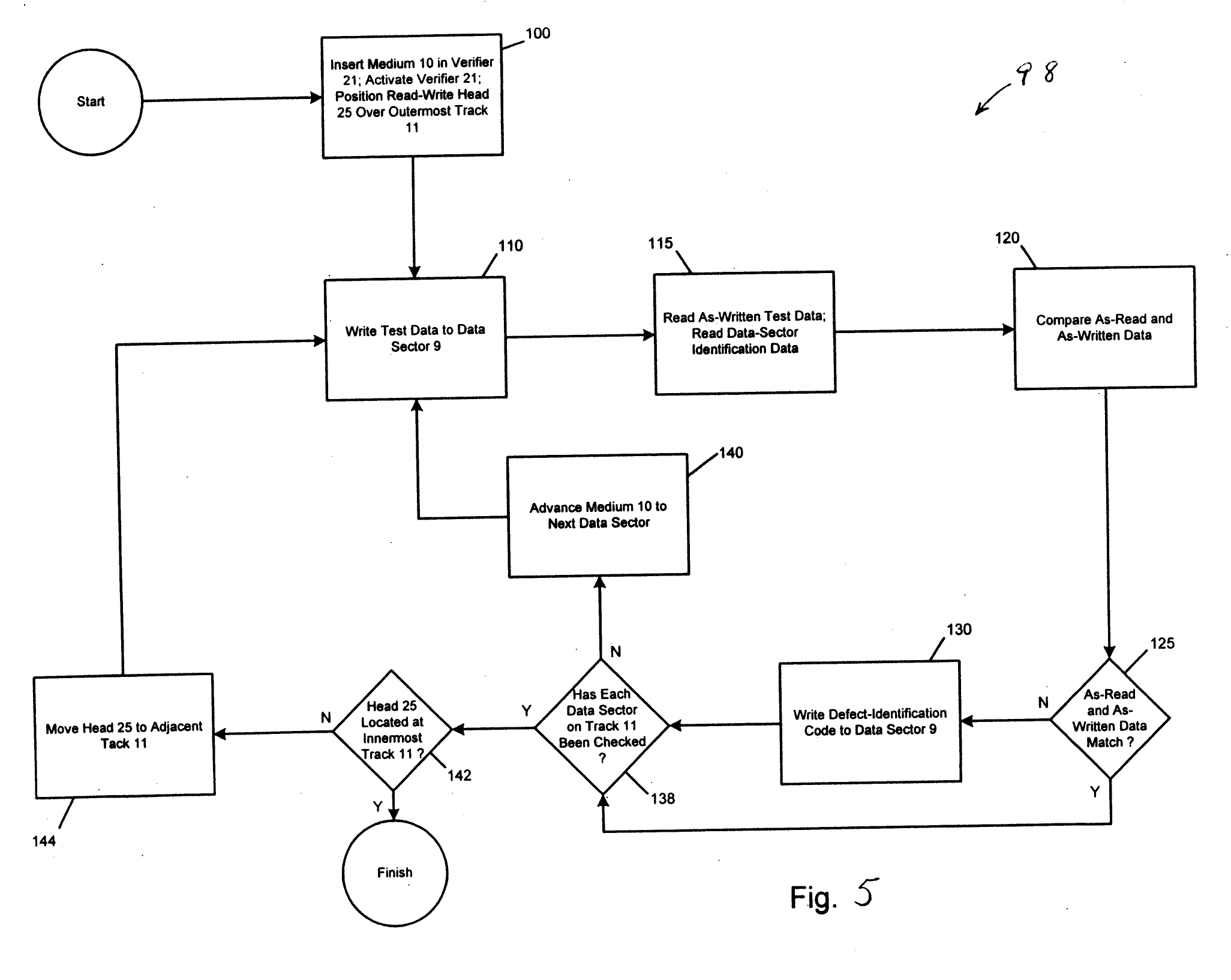

An exemplary verification process 98 is illustrated in FIG. 5. The verification process 98 begins with the insertion of the data-storage medium 10 into the verifier 21, followed by activation of the verifier (step 100). The computer-executable instructions 23, by way of the microprocessor 31, subsequently position the read-write head 25 over an outermost data track 11 on the data-storage medium 10 (step 100).

The verifier 21, as directed by the computer-executable instructions 23, subsequently writes a set of test data to one of the data sectors 9 located along the data track 11 (step 110). The verifier 21 immediately reads back the as-written data (step 115). The verifier 21 also reads the data-sector identification data stored in the data sector 9 (step 115). The computer-executable instructions 23 compare the as-written data to the as-read data (step 120). Discrepancies between the as-written and the as-read data are interpreted as an indication that a particular data sector 9 is defective. A checksum may be included in the test data to assist in the identification of such discrepancies.

Upon encountering a discrepancy between the as-written and the as-read data, the computer-executable instructions 23 write a defect-identification code to the data sector 9 (steps 125, 130). The defect-identification code may be any unique set of data that can be read and recognized by a data-storage device such as the verifier 21. In the exemplary embodiment, the defect-identification code is written to a flag register in the data sector 9. The significance of the defect-identification code is explained in detail below. In addition, the computer-executable instructions 23 write the logical address (or “logical ID”) of the defective data sector 9 (including the number of the data data track 11 on which the defective data sector 9 is located) to a good-sector-identification map.

The data-storage medium 10 is subsequently advanced to a position in which an adjacent data sector 9 is positioned directly under (or over) the read-write head 25 (step 140). (In practice, the data-storage medium 10 is constantly rotating, with the noted read-write operations occurring on a substantially instantaneous basis.) A check of the newly-positioned data sector 9 is subsequently performed in the above-described manner (steps 110-130). This process continues until each data sector 9 on the data track 11 has been checked for defects (step 138). (The computer-executable instructions 23 include logic that tracks the number of data sectors 9 that pass the read-write head 25. The computer-executable instructions 23 compare this number to the total number of data sectors 9 on the data track 11, and thereby determine when all of the data sectors 9 have been checked.)

The read-write head 25 is advanced to an adjacent data track 11 on the data-storage medium 10 when each data sector 9 on the track 11 has been checked for defects (steps 138, 144). The above-noted process is repeated until all of the data sectors 9 on each data track 11 have been checked for defects, i.e., until the innermost track 11 has been checked for defective sectors 9 (step 142). Hence, at the conclusion of the verification process 98, each defective data sector 9 on the data-storage medium 10 includes a defect-identification code is its flag register.

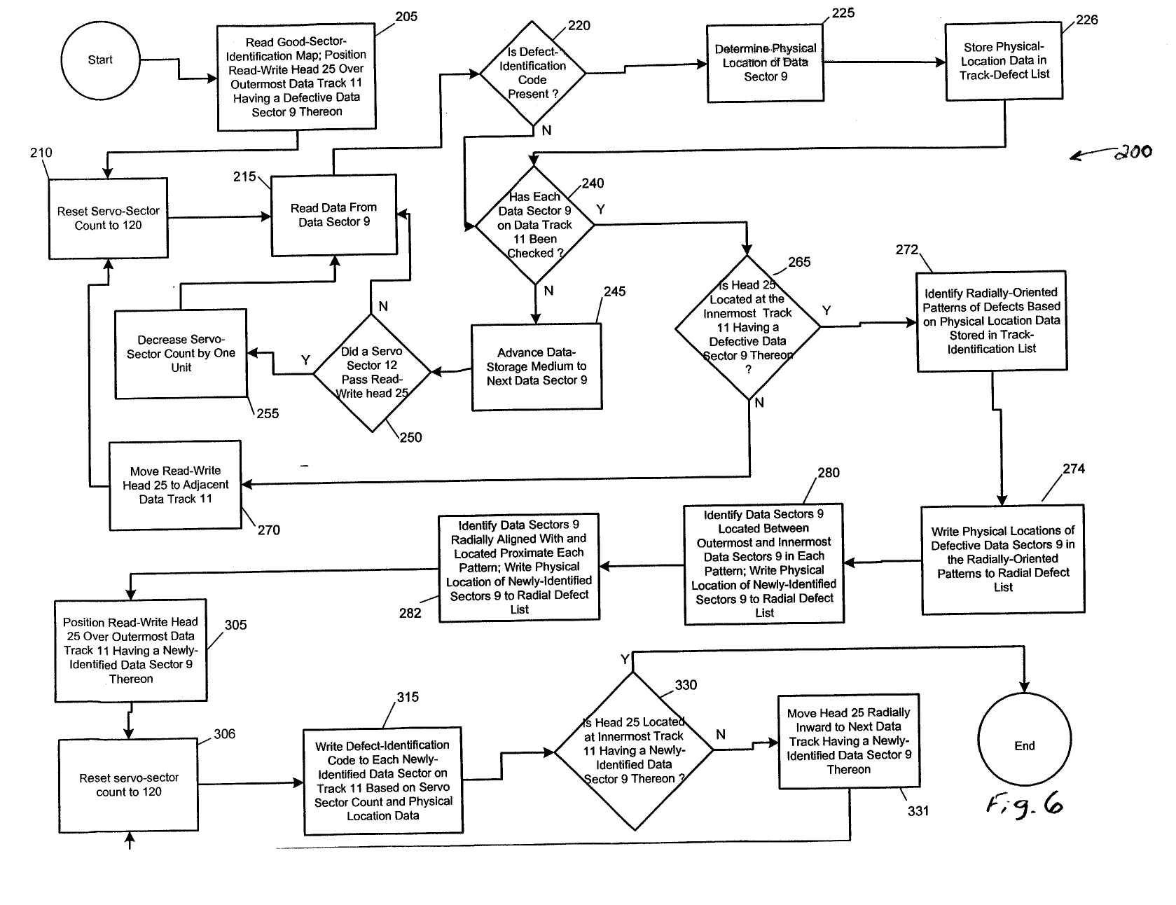

In accordance with the present invention, the data-storage medium 10 is subjected to a process to identify and designate radially-oriented patterns of defects on the medium 10. A presently-preferred version of this process, hereinafter referred to as a “radial-defect-pattern identification process 200,” is depicted in FIG. 6. The radial-defect-identification process 200 comprises identifying radially-oriented patterns of defective data sectors 9 on the medium 10, and ensuring that each data sector 9 encompassed by the patterns has the previously-noted defect-identification code written thereto.

The radial-defect-identification process 200 is preferably performed on the verifier 21 using the computer-executable instructions 23. The process 200 is preferably conducted immediately after the verification process 98. Details concerning the process 200 are as follows.

The radial-defect-designation process 200 begins as the computer-executable instructions 23 read the good-sector-identification map generated during the verification process 98. In addition, the computer-executable instructions 23 initially position the read-write head 25 over the outermost data track 11 on which a defective data sector 9 is located (step 215) (this particular track 11 is identified by the sector-identification map) (step 205). In addition, the computer-executable instructions 23 reset a servo-sector count to 120 (step 210) (the significance of the servo-sector count is explained in detail below).

The read-write head 25 subsequently reads data from the data sectors 9 positioned along the data track 11 (step 215). The computer-executable instructions 23 check the as-read data for the presence of the defect-identification code written during the verification process 98 (step 220).

The computer-executable instructions 23, upon detecting the presence of the defect-identification code in a particular data sector 9, determine the physical location, i.e., the angular and radial positions, of the defective data sector 9 (step 225). More particularly, the computer-executable instructions 23 determine the physical location of the defective data sector 9 based on the current value of the servo-sector count, and the track-location data stored in the defective data sector 9. The computer-executable instructions 23 store the physical-location data in a track-defect list (step 226).

The data-storage medium 10 is subsequently advanced to a position in which an adjacent data sector 9 is positioned directly under (or over) the read-write head 25 (step 245). The computer-executable instructions 23 decrease the servo-sector count by one unit if the read-write head 25 passes one of the servo sectors 12 before reaching the adjacent data sector 9 (steps 250, 255).

The newly-positioned data sector 9 is checked for the presence of the defect-identification code (steps 215, 220). The location of the newly-positioned data sector 9 is stored in the track-defect list if the defect-identification code is present in that sector (steps 225-226). This process is repeated until each data sector 9 on the data track 11 has been checked for the presence of the defect-identification code (step 240). (The computer-executable instructions 23 include logic that tracks the number of data sectors 9 that pass the read-write head 25. The instructions 23 compare this number to the total number of data sectors 9 on the data track 11 to determine when all of the data sectors 9 have been checked.)

The computer-executable instructions 23 subsequently advance the read-write head 25 radially inward to the next data track 11 having a defective data sector 9 located thereon (steps 240, 270). The process of checking each data sector 9 on a particular data track 11 and recording the location of each defective data sector 9 is repeated until all of the data tracks 11 having defective data sectors 9 located thereon have been checked (step 265).

Details concerning the manner in which the physical location, i.e., the radial and angular positions, of each defective data sector 9 is determined are as follows. The radial positions of the defective data sectors 9 are determined from the data stored in each data-sector 9. In particular, each data sector 9 normally includes data that indicates the particular data track 11 on which the data sector 9 is located. The data tracks 11 are concentrically disposed about a center of data-storage surface 10a of the medium 10. Each data track 11 thus occupies a fixed radial position on the data-storage surface 10a. This radial position is unique to each data track 11. Hence, the radial position of a defective data sector 9 can be determined based on the identity of the particular data track 11 on which that data sector 9 is located.

The angular position of each defective servo sector 9 is determined through the use of the servo sector count. In particular, a fixed number of servo sectors 12 are spaced apart in equal angular intervals along each of the data tracks 11, as noted previously. Hence, the passage of each servo sector 12 past the read-write head 25 indicates that the data-storage medium 10 has rotated by a fixed amount in relation to the point at which the preceding servo sector 12 passed the read-write head 25 (this value is three degrees for the exemplary data-storage medium 10 having 120 servo sectors per data track 11).

Thus, the value of the servo-sector count provides an indication of the extent to which medium 10 has rotated after the count was set to its initial value. For example, a count value of 70 in the exemplary embodiment indicates that the data-storage medium 10 has rotated by about 150 degrees after the count was set to its starting value of 120. (This figure represents the number of servo-sectors 12 that have passed the read-write head 25 subsequent to the time at which the count was set to its starting value (120−70=50), multiplied by the angular interval corresponding to the passage of each servo sector 12 (three degrees)).

The extent to which the data-storage medium 10 has rotated after the servo-sector count is set to its starting value provides an indication of the relative angular positions of defective data sectors 9 located along the same data track 11. This indication results from the fact that the servo-sector count for data sectors 9 located along the same track 11 is referenced a common starting point.

The extent of the rotation of medium 10 after the servo-sector count has been set to its starting value also provides an indication of the relative angular positions of the defective data sectors 9 located along different data tracks 11. This characteristic is due to the fact that the servo-sector count is reset each time the data-storage medium 10 completes one full revolution. Hence, the servo-sector count is reset each time the data-storage medium 10 reaches a specific angular position while the data sectors 9 are being checked for the presence of the defect-identification code. Resetting the servo-sector count in this manner allows the positions of defective data sectors 9 located along different data tracks 11 to be referenced to a common angular position on the surface 10a of the data-storage medium 10.

In addition, the computer-executable instructions 23 may comprise additional instructions that cause the servo-sector count to be reset when the read-write head 25 passes a specific predetermined data sector 9. This feature allows the locations of defective data sectors 9 to be referenced to an absolute (vs. relative) position on the surface 10a of the data-storage medium 10. For example, the computer-executable instructions 23 can include a command that resets the servo-sector count when a particular data sector 9 located along the outermost data track 11 of the data-storage medium 10 passes the read-write head 25. Thus, the position of a defective data sector 9 can be identified in relation to a fixed, readily-identifiable point on medium 10, i.e., the angular and radial positions of the predetermined data sector 9. Furthermore, this feature provides a common reference point for multiple checks performed on the same medium 10. Referencing a particular data sector 10 in this manner can also be useful in instances when the servo-sector count is interrupted, e.g., when the read-write head 25 is reset.

The track-defect list generated in the above-described manner thus comprises a listing of the physical locations, i.e., the angular and radial positions, of all the defective data tracks 9 on the data-storage medium 10. This information is used to identify radially-oriented patterns of defects on the data-storage medium 10 (step 272). More particularly, the computer-executable instructions 23 sort the data in the track-defect list to identify groups of defective data sectors 9 having substantially identical angular positions. The presence of a particular number of defective data sectors 9 having a substantially identical angular position, and being located within a predetermined range of radial positions, is interpreted by the computer-executable instructions 23 as a radially-oriented pattern of defects. For example, the presence of five or more defective data sectors 9 located within ten data tracks 11 is recognized as a radially-oriented pattern of defects in the exemplary radial-defect-identification process 200.

The physical location, i.e., the angular and radial position data, of each defective data sector 9 making up the radially-oriented patterns of defects 9 is written to a radial-defect list (step 274). This data is subsequently used by the computer-executable instructions 23 to identify additional data sectors 9 having a predetermined positional relationship with the radially-oriented patterns of defective data sectors 9 (step 280). More particularly, the computer-executable instructions 23 determine the physical location of each data sector 9 located between the radially-outermost and the radially-innermost data sectors 9 in each of the radially-oriented defect patterns. In other words, the computer-executable instructions 23 identify the data sectors 9 having angular locations substantially equal those of the data sectors 9 within a particular defect pattern, and being located on data tracks 11 between the outermost and innermost data tracks 11 located within the pattern. The physical locations of the data sectors 9 identified in this manner are written to the radial-defect list (step 280). This activity, in effect, “fills in” each radially-oriented pattern of defects so that each data sector 9 located between the outermost and the innermost data sectors 9 is identified as part of the pattern.

The computer-executable instructions 23 preferably identify additional data sectors 9 based on further criteria. Specifically, the instructions 23 identify data sectors that are located radially outward and radially inward of a particular radially-oriented defect pattern by a predetermined distance, and that have substantially the same angular position as the defect pattern. The physical locations of the data sectors 9 identified in this manner are written to the radial-defect list (step 282).

More particularly, the computer-executable instructions 23 calculate a radial length of each previously-identified defect pattern based on the radial locations of the outermost and innermost data sectors 9 in the pattern. The computer-executable instruction 23 subsequently extend each end of the pattern by a radial distance equal to approximately fifty-percent of the calculated length of the defect pattern. In other words, the defect pattern is extended radially outward by including data sectors 9 that are radially aligned with the pattern, and that occupy data sectors 9 located radially outward of the pattern by a distance equal to approximately twenty-five percent of the pattern's calculated length. The defect pattern is likewise extended radially inward by including data sectors 9 that are radially aligned with the pattern, and that occupy data sectors 9 located radially inward of the pattern by a distance equal to approximately twenty-five percent of the pattern's calculated length.

The computer-executable instructions 23 subsequently write the previously-referenced defect-identification code to the newly-identified data sectors 9, i.e., to the data sectors 9 identified by filling in and extending the radially-oriented defect patterns, based on the physical location data stored in the radial-defect list. More particularly, the computer-executable instructions 23 write the defect-identification code to the logical address of each newly-identified data sector 9.

The defect-identification code is written to each of the newly-identified data sectors 9 as the logical address of each newly-identified data sector 9 is determined using the previously-referenced servo-sector count. More particularly, the computer-executable instructions 23 position the read-write head 25 over the outermost data track 11 on which one or more of the newly-identified data sectors 9 is located, as the ongoing servo-sector count is reset (steps305, 306). The computer-executable instructions 23 calculate the number of servo sectors 12 that must pass the read-write head 25 before the data-storage medium 10 reaches the angular position of a particular data sector 9. This calculation is based on the previously-noted relationship between the servo-sector spacing and the angular position of the data-storage medium 10. For example, in the exemplary embodiment, the passage of one servo sector 11 past the read-write head 25 signifies that the angular position of the data-storage medium 10 has changed by approximately three degrees in relation to the point a which the prior servo sector 11 passed the read-write head 25.

The computer-executable instructions 23 write the defect-identification code the newly-identified data sector 9 after the calculated number of servo sectors 12 have passed the read-write head 25 (step 315). This process is repeated for the remaining newly-identified data sectors 9 on the data track 11. The computer-executable instructions subsequently advance the read-write head 25 radially inward to the next data track 11 on which a defective data sector 9 is located (step 325). The above-noted activities are repeated until the defect-identification code is written to each of the newly-identified data sectors 9 (steps 330, 331). The verification process 98 and the radial-defect-pattern identification process 200 can then be repeated for the opposite side of the data storage medium 10 (if the data-storage medium 10 is a double-sided medium).

In sum, the process provided by the present invention identifies radially-aligned patterns of defects on the data-storage medium 10. Each pattern is then “filled in” by ensuring that each data-sector 9 encompassed by the pattern has a defect-identification code written thereto. In addition, each radially-oriented pattern is extended to include radially-aligned data sectors 9 located outside of the initially-identified pattern, but within a predetermined distance from the pattern.

Identifying and designating the radially-aligned defect patterns in the above-noted manner substantially reduces the possibility of hard, non-recoverable read-write errors associated with such defect patterns when the data-storage medium 10 is used with a different head-disk interface that of the verifier 21, e.g., when the data-storage medium 10 is used in the disk drive of the end user. More particularly, the head-disk interface of an end user's disk drive often is not as tolerant of imperfections in the data-storage surface of a data-storage medium (such as the medium 10) as the verifier 21. Hence, the end user's disk drive may be unable to write and read data to and from data sectors 9 that were identified as non-defective during the verification process 98. Such data sectors 9 often occur within, or proximate a radially-oriented pattern of defects. Hence, “filling in” and “extending” such a pattern can reduce the occurrence of hard, non-recoverable read-write errors often associated with these data sectors 9. Furthermore, extending the defect pattern lessens the possibility of errors resulting from the growth of the defect pattern over the life of the data-storage medium 10.

The present invention is particularly advantageous in light of the ongoing pressures on producers of data-storage media to increase the aerial density of their products by reducing data-track spacing. Reductions in data-track spacing on a data-storage medium reduce the tolerance of a head-disk interface to imperfections in the medium. Hence, the present invention facilitates the use of smaller track spacing by identifying additional data sectors that are likely to provide unsatisfactory performance under such conditions, and ensuring that those data sectors will not be written to or read from by the end user's device.

It is to be understood that even though numerous characteristics and advantages of the present invention have been set forth in the foregoing description, together with specific details of the invention, the disclosure is illustrative only, and changes may be made in detail, especially in matters of shape, size, and arrangement of the parts, within the principles of the invention to the full extent indicated by the broad general meaning of the terms in which the appended claims are expressed.

What is claimed is:

1. A process for identifying and designating a radially-oriented defect pattern on a data-storage medium, comprising:
determining an angular position of one or more pre-identified defective data sectors on the data-storage medium by counting a number of servo sectors on the data-storage medium that pass a predetermined reference point;
defining a radially-oriented pattern of the pre-identified defective data sectors based on a predetermined relationship between (i) a number of the pre-identified defective data sectors having substantially identical angular positions and (ii) radial spacing between the pre-identified defective data sectors having substantially identical angular positions; and
writing defect-identification information to data sectors having locations that substantially coincide with the radially-oriented pattern of the pre-identified defective data sectors.

2. The process of claim 1, further comprising writing the defect-identification information to data sectors having (i) substantially identical angular positions as the pattern of the pre-identified defective data sectors and (ii) radial positions located within a predetermined distance from the pattern of the pre-identified defective data sectors.

3. The process of claim 1, wherein the predetermined relationship is five of the pre-identified defective data sectors having substantially identical angular positions being located within ten consecutive data tracks on the data-storage medium.

4. The process of claim 2, wherein the predetermined distance is approximately twenty-five percent of a length of the pattern of the pre-identified defective data sectors.

5. The process of claim 1, further comprising determining a radial position of the one or more pre-identified defective data sectors by reading data-track location data from the one or more pre-identified defective data sectors.

6. A process for identifying and designating a radially-oriented pattern of potentially unusable data sectors on a data-storage medium having servo sectors and data tracks defined thereon, comprising:
reading a defect-identification code from pre-identified defective data sectors on the data-storage medium;
calculating angular positions of the pre-identified defective data sectors by counting a number of the servo sectors that pass a predetermined reference point and correlating the number with an angular displacement of the data-storage medium;
determining radial positions of the pre-identified defective data sectors based on positions of the data tracks on which the pre-identified defective data sectors are located;
defining a radially-oriented defect pattern by identifying a predetermined number of the pre-identified defective data sectors that (i) have substantially identical angular positions and (ii) are located within a predetermined radial distance of each other; and
writing the defect-identification code to one or more data sectors, other than the pre-identified defective data sectors, having (i) an angular position that is substantially identical to an angular position of the radially-oriented defect pattern and (ii) a radial position between a radially outermost and a radially innermost of the pre-identified defective data sectors in the radially-oriented defect pattern.

7. The process of claim 6, wherein the predetermined number of data sectors is five and the predetermined radial distance is a distance corresponding to a spacing between ten consecutive data tracks.

8. The process of claim 6, further comprising writing the defect-identification code to one or more data sectors, other than the pre-identified defective data sectors, having (i) an angular position that is substantially identical to the angular position of the radially-oriented defect pattern and (ii) a radial position located within a predetermined distance radially outward of the radially-outermost of the pre-identified defective data sectors in the radially-oriented defect pattern.

9. The process of claim 8, wherein the predetermined distance is approximately one-fourth of a length of the radially-oriented defect pattern.

10. The process of claim 8, further comprising writing the defect-identification code to one or more data sectors, other than the pre-identified defective data sectors, having (i) an angular position substantially identical to the angular position of the radially-oriented defect pattern and (ii) a radial position located within a second predetermined distance radially inward of the radially-innermost of the pre-identified defective data sectors in the radially-oriented defect pattern.

11. The process of claim 10, wherein the second predetermined distance is approximately one-fourth of a length of the radially-oriented defect pattern.

12. The process of claim 6, wherein counting a number of the servo sectors that pass a predetermined reference point comprises setting a servo-sector count to a predetermined value and decreasing the servo-sector count when one of the servo-sectors passes the predetermined reference point.

13. The process of claim 6, wherein counting a number of the servo sectors that pass a predetermined reference point comprises counting a number of the servo sectors that pass a read-write head of a disk drive.

14. The process of claim 13, further comprising moving the read-write head from a location proximate one of the data tracks to a location proximate another of the data tracks when the servo-sector count reaches a second predetermined value.

15. The process of claim 6, further comprising identifying the one or more data sectors, other than the pre-identified defective data sectors, by counting a second number of the servo sectors that pass the predetermined reference point and correlating the second number to the angular position of the data-storage medium.

16. A process for marking a pattern of potentially unusable data sectors on a data-storage medium, comprising:
checking data sectors on the data-storage medium for the presence of a pre-written defect-identification code;
determining angular and radial positions of the data sectors having the defect-identification code pre-written thereto;
identifying the pattern of potentially unusable data sectors by checking for a predetermined number of the data sectors having the defect-identification code written thereto that (i) have substantially identical angular positions and (ii) are radially spaced within a predetermined distance; and
filling in and extending the pattern of potentially unusable data sectors.

17. The process of claim 16, wherein filling in and extending the pattern of potentially unusable data sectors comprises writing the defect-identification code to data sectors, other than the data sectors having the defect-identification code pre-written thereto, having (i) angular positions substantially identical to the pattern of potentially unusable data sectors and (ii) radial positions located between a radially outmost and a radially innermost of the data sectors in the pattern of potentially unusable data sectors.

18. The process of claim 16, wherein filling in and extending the pattern of potentially unusable data sectors comprises:
writing the defect-identification code to data sectors, other than the data sectors having the defect-identification code pre-written thereto, having (i) angular positions substantially identical to the pattern of potentially unusable data sectors and (ii) radial positions located radially outward of the radially outermost data sector by a predetermined distance; and
writing the defect-identification code to data sectors, other than the data sectors having the defect-identification code pre-written thereto, having (i) angular positions substantially identical to the pattern of potentially unusable data sectors and (ii) radial positions located radially inward of the radially innermost data sector by a predetermined distance.

19. The process of claim 16, wherein determining angular positions of the data sectors having the defect-identification code-pre written thereto comprises counting a number of servo sectors on the data-storage medium that pass a predetermined reference point and correlating the number with an angular displacement of the data-storage medium.

20. A process for identifying and designating a radially-oriented defect pattern on a substantially circular data-storage medium, comprising:
determining an angular position of one or more pre-identified defective data sectors on the data-storage medium;
defining a radially-oriented pattern of the pre-identified defective data sectors based on a predetermined relationship between (i) a number of the pre-identified defective data sectors having substantially identical angular positions and (ii) radial spacing between the pre-identified defective data sectors having substantially identical angular positions; and
writing predetermined identification information to data sectors having locations that substantially coincide with the radially-oriented pattern of the pre-identified defective data sectors.

21. A process for identifying and designating a radially-oriented defect pattern on a substantially circular data-storage medium, comprising:
determining an angular position of a defective data sector on the data-storage medium by counting a number of servo sectors on the data-storage medium that pass a predetermined reference point; and
determining a radial position of the defective data sector based on a location of a data-track on which the defective data sector is positioned.

22. A device for identifying and designating a radially-oriented defect pattern on a data-storage medium, comprising:
a microprocessor;
a memory-storage device electrically coupled to the microprocessor;
a read-write head electrically coupled to the microprocessor for writing and reading information to and from the data-storage medium; and
a set of computer-executable instructions stored on the memory-storage device, wherein the computer-executable instructions:
determine an angular position of one or more pre-identified defective data sectors on the data-storage medium by counting a number of servo sectors on the data-storage medium that pass a predetermined reference point;
define a radially-oriented pattern of the pre-identified defective data sectors based on a predetermined relationship between (i) a number of the pre-identified defective data sectors having substantially identical angular positions and (ii) radial spacing between the pre-identified defective data sectors having substantially identical angular positions; and
cause the read-write head to write defect-identification information to data sectors having locations that substantially coincide with the radially-oriented pattern of the pre-identified defective data sectors.

23. The system of claim 22, further comprising:
a suspension arm mechanically coupled to the read-write head for suspending and moving the read-write head over a surface of the data-storage medium;
an actuator mechanically coupled to the suspension arm and electrically coupled to the microprocessor for moving the arm in response to commands from the microprocessor; and
a spindle for supporting and rotating the data-storage medium.
